(19) United States
(12) Patent Application Publication
(10) Pub. No.: US 2025/0231481 A1
(43) Pub. Date: Jul. 17, 2025

(54) PHOTORESIST COMPOSITIONS AND METHODS OF MANUFACTURING INTEGRATED CIRCUIT DEVICES BY USING THE SAME

(71) Applicant: Samsung Electronics Co., Ltd., Suwon-si (KR)

(72) Inventors: Yonghoon Moon, Suwon-si (KR); Honggu Im, Suwon-si (KR); Seungchul Kwon, Suwon-si (KR); Yechan Kim, Suwon-si (KR); Hana Kim, Suwon-si (KR); Sungan Do, Suwon-si (KR)

(21) Appl. No.: 18/946,157

(22) Filed: Nov. 13, 2024

(30) Foreign Application Priority Data
Jan. 16, 2024 (KR) 10-2024-0006806

(51) Int. Cl. G03F 7/039; G03F 7/00; H01L 21/027

(52) U.S. Cl. CPC G03F 7/039; G03F 7/70025; G03F 7/70033; H01L 21/0274

(57) ABSTRACT

Provided are photoresist compositions and methods of manufacturing an integrated circuit device by using the same. The photoresist compositions include a photosensitive polymer and a solvent, wherein the photosensitive polymer comprises a pyridinium salt and a functional group convertible (e.g., capable of being converted) to a radical and bonded to the pyridinium salt, and the functional group convertible to the radical comprises an oxygen atom, a nitrogen atom or a carbon atom bonded to a nitrogen atom of the pyridinium salt, and is able to generate the radical by decomposition of a bond between the oxygen atom, the nitrogen atom or the carbon atom of the functional group convertible to the radical and the nitrogen atom of the pyridinium salt.

### CROSS-REFERENCE TO RELATED APPLICATION

This application claims priority under 35 U.S.C. § 119 to Korean Patent Application No. 10-2024-0006806, filed on Jan. 16, 2024, in the Korean Intellectual Property Office, the disclosure of which is incorporated by reference herein in its entirety.

### FIELD

The inventive concept relates to photoresist compositions and methods of manufacturing an integrated circuit device by using the photoresist compositions, and more particularly, to photoresist compositions including a pyridinium salt and methods of manufacturing an integrated circuit device by using the photoresist compositions.

### BACKGROUND

Due to the advancement of electronic technology, integrated circuit devices have been rapidly down-scaled. Demand remains for photolithography processes that are advantageous in implementing fine patterns.

### SUMMARY

In an aspect, the inventive concept provides a photoresist composition capable of providing excellent etch resistance and resolution in a photolithography process for manufacturing an integrated circuit device.

In an aspect, the inventive concept also provides a method of manufacturing an integrated circuit device, the method being capable of improving the dimensional precision of patterns intended to be formed, by providing excellent etch resistance and resolution.

However, the inventive concept is not limited to the aspects set forth above, and the above and other aspects of the inventive concept will be clearly understood by those of ordinary skill in the art from the following description.

According to an aspect of the inventive concept, there is provided a photosensitive polymer and a solvent, wherein the photosensitive polymer comprises a pyridinium salt and a functional group convertible (e.g., capable of being converted) to a radical and bonded to the pyridinium salt, and the functional group convertible to the radical comprises an oxygen atom, a nitrogen atom or a carbon atom bonded to a nitrogen atom of the pyridinium salt, and is able to generate the radical by decomposition of a bond between the oxygen atom, the nitrogen atom or the carbon atom of the functional group convertible to the radical and the nitrogen atom of the pyridinium salt.

According to another aspect of the inventive concept, there is provided a photoresist composition including a photosensitive polymer and a solvent, wherein the photosensitive polymer includes a pyridinium salt and a functional group convertible to a radical and bonded to the pyridinium salt, the functional group convertible to a radical being included in a main chain of the photosensitive polymer.

According to another aspect of the inventive concept, there is provided a method of manufacturing an integrated circuit device, the method including forming a photoresist film on a feature layer by using any of the photoresist composition as described above, generating a radical from the photosensitive polymer in a first region, which is a portion of the photoresist film, through exposure of the first region to light, and inducing a change in polarity of the photosensitive polymer by converting the pyridinium salt of the photosensitive polymer into a pyridine group, and forming a photoresist pattern including a non-light-exposed region of the photoresist film by removing the light-exposed first region from the photoresist film by using a developer.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing an integrated circuit device, according to some embodiments; and

FIGS. 2A to 2E are cross-sectional views respectively illustrating a sequence of processes of a method of manufacturing an integrated circuit device, according to some embodiments.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted.

Herein, when a chemical bond is not shown at a position at which the chemical bond has to be drawn in a formula, this may mean that a hydrogen atom is bonded to the position, unless otherwise defined. Herein, “pyridinium salt” described in connection with the photosensitive polymer should be understood as “pyridinium salt group”, for example, “the photosensitive polymer includes a pyridinium salt” should be understood as “the photosensitive polymer includes a pyridinium salt group”.

A photoresist composition according to some embodiments may include a photosensitive polymer and a solvent.

In some embodiments, the photosensitive polymer may include a pyridinium salt and a functional group convertible (e.g., capable of being converted) to a radical, the functional group convertible to a radical being bonded to the pyridinium salt.

The term “functional group convertible to a radical” used herein may refer to a substituted or unsubstituted functional group having a linear structure, a cyclic structure, or a mixed structure thereof and including an oxygen atom, a nitrogen atom or a carbon atom, bonded to a nitrogen atom of a pyridinium salt. The term “substituted” used herein means that at least one hydrogen atom bonded to a carbon atom is substituted with a substituent or at least one carbon atom is substituted with a hetero-element-containing group, unless otherwise defined. The substituent may include, for example, a halogen element, a hydroxyl group, an aldehyde group, a carboxyl group, an amino group, a cyano group, an isocyanate group, a thiol group, a sulfonic acid group or a salt thereof, a phosphoric acid group or a salt thereof, a C1 to C30 (e.g., C1 to C20, C1 to C10, or C1 to C6) alkyl group, a C3 to C30 (e.g., C3 to C20, C3 to C10, or C5 to C7) cycloalkyl group, a C2 to C30 (e.g., C2 to C20, C2 to C10, or C2 to C6) alkenyl group, a C1 to C30 (e.g., C1 to C20, C1 to C10, or C1 to C6) alkoxy group, a C2 to C30 (e.g., C2 to C20, C2 to C10, or C2 to C6) alkenoxy group, a C2 to C30 (e.g., C2 to C20, C2 to C10, or C2 to C6) alkynyl group, a C6 to C30 (e.g., C6 to C20, C6 to C12, or C6 to C10) aryl group, a C6 to C30 (e.g., C6 to C20, C6 to C12, or C6 to C10) aryloxy group, a C7 to C30 (e.g., C7 to C20, C7 to C13, or C7 to C11) alkylaryl group, a C7 to C30 (e.g., C7 to C20, C7 to C13, or C7 to C11) arylalkyl group, a C7 to C30 (e.g., C7 to C20, C7 to C13, or C7 to C11) alkylaryloxy group, or a C3 to C30 (e.g., C3 to C20, C3 to C12, C3 to C10, or C3 to C8) heteroaryl group. The hetero-element-containing group may also be referred to as a hetero-atom-containing group. The hetero-element-containing group may include, for example, —O—, —C(═O)—O—, —O—C(═O)—, —C(═O)—, —O—C(═O)—O—, —C(═O)—NH—, —NH—, —S—, —S(═O)₂—, or —S(═O)₂—O—. However, the functional group convertible to a radical is not limited to the functional groups set forth above as examples and may include various functional groups capable of generating radicals.

Herein, as to a substituted X group (X group is C1 to C30 alkyl group, C5 to C30 alkyl group, C2 to C30 alkenyl group, C5 to C30 alkenyl group, C2 to C30 alkynyl group, C3 to C30 cycloalkyl group, C1 to C30 alkoxy group, C2 to C30 acyl group, C7 to C30 alkylbenzenesulfonyl group, C6 to C30 aryl group, C3 to C30 heteroaryl group, or C7 to C30 arylalkyl group), preferably, the upper limit of the carbon number in the X group may be C20, C15, C14, C12, C10, C8, C7, or C6. For example, the C1 to C30 alkyl group may preferably be C1 to C20 alkyl group, C1 to C10 alkyl group, or C1 to C6 alkyl group. The C6 to C30 aryl group may preferably be C6 to C20 aryl group, C6 to C12 aryl group, or C6 to C10 aryl group. The C7 to C30 alkylbenzenesulfonyl group may preferably be C7 to C20 alkylbenzenesulfonyl group, C7 to C15 alkylbenzenesulfonyl group, or C7 to C10 alkylbenzenesulfonyl group. C7 to C30 in the C7 to C30 alkylbenzenesulfonyl refers to the total carbon number in the alkylbenzenesulfonyl. The C3 to C30 heteroaryl group may preferably be C3 (or C6) to C20 heteroaryl group, C3 (or C6) to C12 heteroaryl group, C3 (or C6) to C10 heteroaryl group, or C3 (or C6) to C8 heteroaryl group.

In some embodiments, the functional group convertible to a radical may generate by decomposition of a bond between the oxygen atom, the nitrogen atom or the carbon atom of the functional group convertible to the radical and the nitrogen atom of the pyridinium salt.

In some embodiments, the photosensitive polymer may include a first repeating unit represented by one of the structures of Formulae 1.

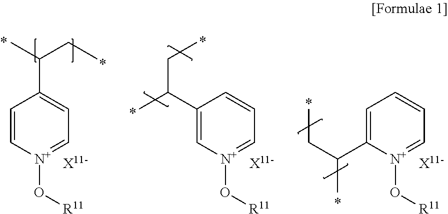

In Formulae 1, OR¹¹ may be a functional group convertible to a radical. R¹¹ may be a substituted or unsubstituted C1 to C30 alkyl group, a substituted or unsubstituted C2 to C30 alkenyl group, or a substituted or unsubstituted C7 to C30 arylalkyl group. X¹¹⁻ may be a nonmetallic element or a compound anion. Herein, the nonmetallic element anion consists of only one nonmetallic element, for example, the nonmetallic element anion may be halogen anion such as F⁻, Cl⁻, Br⁻, or I⁻. The compound anion is different from the nonmetallic element anion, and comprises at least two elements. The compound anion may include an anion derived from a compound such as an organic compound and a negatively-charged atom group. For example, X¹¹⁻ may include 4-methylbenzenesulfonate (OTs), BF₄⁻, or PF₆⁻. * represents a binding site.

In some embodiments, R¹¹ may be a substituted C5 to C30 alkyl group, in which at least one hydrogen atom bonded to a carbon atom at position 1, 5, or 6 is substituted with a secondary or higher (e.g., tertiary) substituent or a carbon atom at position 1, 5, or 6 is substituted with a hetero-element-containing group, such that a 1,5-hydrogen atom transfer reaction may occur. The substituent may include, for example, secondary amides, tertiary amides, secondary alcohols, tertiary alcohols, secondary alkyl halides, tertiary alkyl halides, secondary amines, tertiary amines, secondary ketimines, secondary aldimines, or the like. The substituent may have a carbon atom number of 2 to 20, for example, 3 to 18, 4 to 15, or 5 to 10. The hetero-element-containing group may include, for example, —O—, —C(═O)—O—, —O—C(═O)—, —C(═O)—, —O—C(═O)—O—, —C(═O)—NH—, —NH—, —S—, —S(═O)₂—, or —S(═O)₂—O—.

In some embodiments, R¹¹ may be a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7, such that an intramolecular cyclization reaction may occur.

For example, the photosensitive polymer may include a first repeating unit represented by a structure shown below.

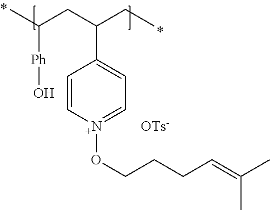

In the above structure, OTs⁻ indicates 4-methylbenzenesulfonate anion, and * represents a binding site.

In some embodiments, the photosensitive polymer may include a first repeating unit represented by one of the structures of Formulae 1-1.

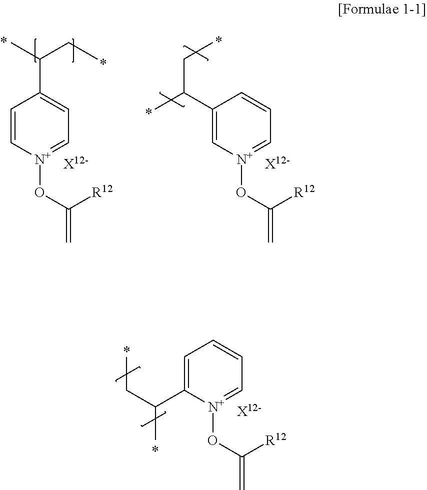

In Formulae 1-1, R¹² may be hydrogen, a C1 to C30 alkyl group, a C2 to C30 alkenyl group, a C2 to C30 alkynyl group, a C3 to C30 cycloalkyl group, a C1 to C30 alkoxy group, a C6 to C30 aryl group, a C3 to C30 heteroaryl group, a C7 to C30 arylalkyl group, or a phenyl group. X¹²⁻ may be a nonmetallic element or a compound anion. For example, X¹²⁻ may include OTs, BF₄, or PF₆. * represents a binding site.

In some embodiments, the photosensitive polymer may include a second repeating unit represented by one of the structures of Formulae 2.

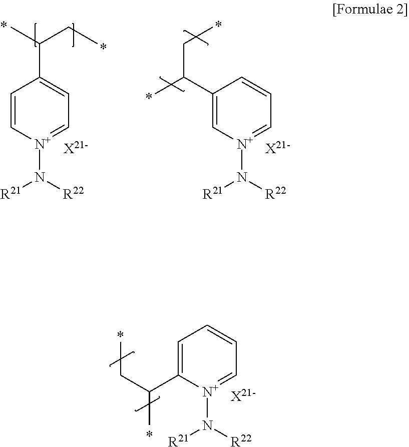

In Formulae 2, NR²¹ may be a functional group convertible to a radical. R²¹ may be a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, or a substituted or unsubstituted C7 to C30 alkylbenzenesulfonyl group. R²² may be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C2 to C30 acyl group, a substituted or unsubstituted C7 to C30 alkylbenzenesulfonyl group, a substituted or unsubstituted C6 to C30 aryl group, a substituted or unsubstituted C3 to C30 heteroaryl group, a substituted or unsubstituted C7 to C30 arylalkyl group, or a substituted or unsubstituted phenyl group. X²¹⁻ may be a nonmetallic element or a compound anion. For example, X²¹⁻ may include OTs, BF₄, or PF₆. * represents a binding site.

In some embodiments, R²¹ may be a substituted C5 to C30 alkyl group, in which at least one hydrogen atom bonded to a carbon atom at position 1, 5, or 6 is substituted with a secondary or higher (e.g., tertiary) substituent or a carbon atom at position 1, 5, or 6 is substituted with a hetero-element-containing group, such that a 1,5-hydrogen atom transfer reaction may occur. The substituent may include, for example, secondary amides, tertiary amides, secondary alcohols, tertiary alcohols, secondary alkyl halides, tertiary alkyl halides, secondary amines, tertiary amines, secondary ketimines, secondary aldimines, or the like. The substituent may have a carbon atom number of 2 to 20, for example, 3 to 18, 4 to 15, or 5 to 10. The hetero-element-containing group may include, for example, —O—, —C(═O)—O—, —O—C(═O)—, —C(═O)—, —O—C(═O)—O—, —C(═O)—NH—, —NH—, —S—, —S(═O)₂—, or —S(═O)₂—O—.

In some embodiments, R²¹ may be a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7, such that an intramolecular cyclization reaction may occur.

For example, the photosensitive polymer may include a second repeating unit represented by a structure shown below.

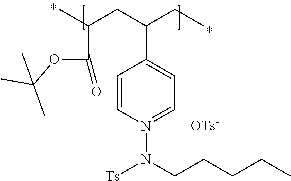

In the above structure, OTs⁻ indicates 4-methylbenzenesulfonate anion, Ts indicates 4-methylbenzenesulfonyl group, and * represents a binding site.

In some embodiments, the photosensitive polymer may include a third repeating unit represented by one of the structures of Formulae 3.

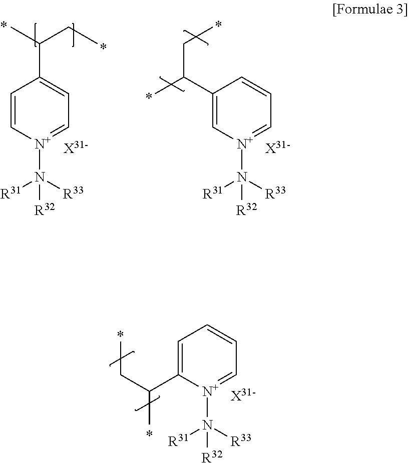

In Formulae 3, CR³¹ may be a functional group convertible to a radical. R³¹ may be a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, or a substituted or unsubstituted C7 to C30 alkylbenzenesulfonyl group. R³² and R³³ may each independently be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C2 to C30 acyl group, a substituted or unsubstituted C7 to C30 alkylbenzenesulfonyl group, a substituted or unsubstituted C6 to C30 aryl group, a substituted or unsubstituted C3 to C30 heteroaryl group, a substituted or unsubstituted C7 to C30 arylalkyl group, or a substituted or unsubstituted phenyl group. X³¹⁻ may be a nonmetallic element or a compound anion. For example, X³¹⁻ may include OTs, BF₄, or PF₆. * represents a binding site.

In some embodiments, R³¹ may be a substituted C5 to C30 alkyl group, in which at least one hydrogen atom bonded to a carbon atom at position 1, 5, or 6 is substituted with a secondary or higher (e.g., tertiary) substituent or a carbon atom at position 1, 5, or 6 is substituted with a hetero-element-containing group, such that a 1,5-hydrogen atom transfer reaction may occur. The substituent may include, for example, secondary amides, tertiary amides, secondary alcohols, tertiary alcohols, secondary alkyl halides, tertiary alkyl halides, secondary amines, tertiary amines, secondary ketimines, secondary aldimines, or the like. The substituent may have a carbon atom number of 2 to 20, for example, 3 to 18, 4 to 15, or 5 to 10. The hetero-element-containing group may include, for example, —O—, —C(═O)—O—, —O—C(═O)—, —C(═O)—, —O—C(═O)—O—, —C(═O)—NH—, —NH—, —S—, —S(═O)₂—, or —S(═O)₂—O—.

In some embodiments, R³¹ may be a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7, such that an intramolecular cyclization reaction may occur.

In some embodiments, the photosensitive polymer may include, in a main chain thereof, a main chain scission (MCS) structure, which forms a free radical to induce the scission of the main chain. In some embodiments, the photosensitive polymer may include, in the main chain thereof, a functional group convertible to a radical.

In some embodiments, the photosensitive polymer may include an 11th repeating unit and a 12th repeating unit, which are each represented by one of the structures of Formulae 1 described above. The 11th repeating unit and the 12th repeating unit may each independently include R¹¹ selected from a substituted or unsubstituted C1 to C30 alkyl group, a substituted or unsubstituted C2 to C30 alkenyl group, a substituted or unsubstituted C1 to C30 alkoxy group, and a substituted or unsubstituted C7 to C30 arylalkyl group.

In some embodiments, in the photosensitive polymer, R¹¹ of the 11th repeating unit may be bonded to a binding site of a main chain of the twelfth repeating unit. In this case, R¹¹ of the 11th repeating unit is a corresponding divalent group. In other words, R¹¹ of the 11th repeating unit is a substituted or unsubstituted C1 to C30 alkylene group, a substituted or unsubstituted C2 to C30 alkenylene group, a substituted or unsubstituted C1 to C30 alkyleneoxy group, or a substituted or unsubstituted C7 to C30 arylalkylene group. For example, the photosensitive polymer may include a —[C₂H₃]ₙ—R¹¹—O— structure. For example, “n” is a natural number in the range from 1 to 100.

In some embodiments, the photosensitive polymer may include an 11th repeating unit and a 12th repeating unit, which are each represented by one of the structures of Formulae 1-1 described above. The 11th repeating unit and the 12th repeating unit may each independently include R¹² selected from hydrogen, a C1 to C30 alkyl group, a C2 to C30 alkenyl group, a C2 to C30 alkynyl group, a C3 to C30 cycloalkyl group, a C1 to C30 alkoxy group, a C6 to C30 aryl group, a C3 to C30 heteroaryl group, a C7 to C30 arylalkyl group, and a phenyl group.

In some embodiments, in the photosensitive polymer, R¹² of the 11th repeating unit may be bonded to a binding site of a main chain of the 12th repeating unit. In this case, R¹² of the 11th repeating unit is a corresponding divalent group. For example, the photosensitive polymer may include a —[C₂H₃]ₙ—R¹²—O— structure. For example, “n” is a natural number in the range from 1 to 100.

In some embodiments, the photosensitive polymer may include a fourth repeating unit represented by Formula 4.

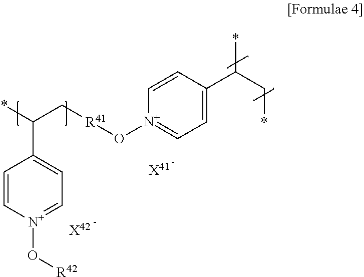

In Formula 4, OR⁴¹ and OR⁴² may each be a functional group convertible to a radical. R⁴¹ may be a substituted or unsubstituted C1 to C30 alkylene group, a substituted or unsubstituted C2 to C30 alkenylene group, or a substituted or unsubstituted C7 to C30 arylalkylene group. R⁴² may be a substituted or unsubstituted C1 to C30 alkyl group, a substituted or unsubstituted C2 to C30 alkenyl group, or a substituted or unsubstituted C7 to C30 arylalkyl group. X⁴¹ and X⁴² may be a nonmetallic element or a compound anion. For example, X⁴¹ and X⁴² may each independently be OTs, BF₄, or PF₆. * represents a binding site.

In some embodiments, R⁴¹ and R⁴² may each independently include a functional group that is similar to the examples of R¹¹ in Formulae 1 described above, except that R⁴¹ becomes a corresponding divalent group. R⁴¹ and R⁴² may each independently be a substituted C5 to C30 alkyl group, in which at least one hydrogen atom bonded to a carbon atom at position 1, 5, or 6 is substituted with a secondary or higher (e.g., tertiary) substituent or a carbon atom at position 1, 5, or 6 is substituted with a hetero-element-containing group, or R⁴¹ and/or R⁴² may each independently be a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7. A detailed description about the secondary or higher (e.g., tertiary) substituent may refer to that described above in connection with R¹¹ in Formula 1.

For example, the photosensitive polymer may include a fourth repeating unit represented by a structure shown below.

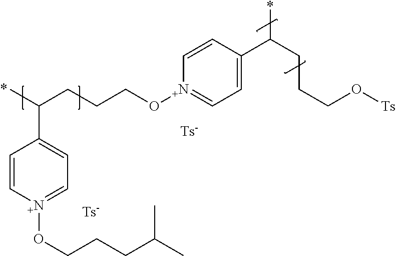

In the above structure, * represents a binding site.

In some embodiments, the photosensitive polymer may include a 21st repeating unit and a 22nd repeating unit, which are each represented by one of the structures of Formula 2 described above. The 21st repeating unit and the 22nd repeating unit may each independently include R²¹ selected from a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, and a substituted or unsubstituted C7 to C30 alkylbenzenesulfonyl group.

In some embodiments, in the photosensitive polymer, R²² of the 21st repeating unit may be bonded to a binding site of a main chain of the 22nd repeating unit. In this case, R²² of the 21st repeating unit is a corresponding divalent group. For example, the photosensitive polymer may include a —[C₂H₃]ₙ—R²²—N— structure. For example, “n” is a natural number in the range from 1 to 100.

In some embodiments, the photosensitive polymer may include a fifth repeating unit represented by Formula 5.

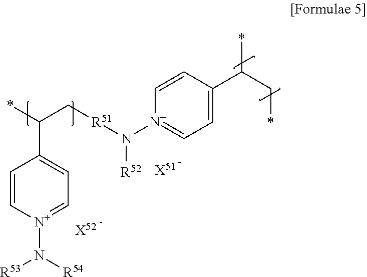

In Formula 5, NR⁵¹ and NR⁵³ may each be a functional group convertible to a radical. R⁵¹ may be a substituted or unsubstituted C1 to C30 alkylene group, a substituted or unsubstituted C2 to C30 alkenylene group, a substituted or unsubstituted C1 to C30 alkyleneoxy group, a substituted or unsubstituted C7 to C30 arylalkylene group, a substituted or unsubstituted C2 to C30 acylene group, or a substituted or unsubstituted C7 to C30 divalent alkylbenzenesulfonyl group. R⁵³ may be a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, or a substituted or unsubstituted C7 to C30 alkylbenzenesulfonyl group. R⁵² and R⁵⁴ may each independently be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C2 to C30 acyl group, a substituted or unsubstituted C7 to C30 alkylbenzenesulfonyl group, a substituted or unsubstituted C6 to C30 aryl group, a substituted or unsubstituted C3 to C30 heteroaryl group, a substituted or unsubstituted C7 to C30 arylalkyl group, or a substituted or unsubstituted phenyl group. X⁵¹ and X⁵² may be a nonmetallic element or a compound anion. For example, X⁵¹ and X⁵² may each independently be OTs, BF₄, or PF₆. * represents a binding site.

In some embodiments, R⁵¹ and R⁵³ may each independently include a functional group that is similar to the examples of R²¹ in Formulae 2 described above, except that R⁵¹ becomes a corresponding divalent group. R⁵¹ and R⁵³ may each independently be a substituted C5 to C30 alkyl group, in which at least one hydrogen atom bonded to a carbon atom at position 1, 5, or 6 is substituted with a secondary or higher (e.g., tertiary) substituent or a carbon atom at position 1, 5, or 6 is substituted with a hetero-element-containing group, or R⁵¹ and/or R⁵³ may each independently be a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7. A detailed description about the secondary or higher (e.g., tertiary) substituent may refer to that described above in connection with R²¹ in Formula 2.

In some embodiments, the photosensitive polymer may include a 31st repeating unit and a 32nd repeating unit, which are each represented by one of the structures of Formulae 3 described above. The 31st repeating unit and the 32nd repeating unit may each independently include R³¹ selected from a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, and a substituted or unsubstituted C7 to C30 alkylbenzenesulfonyl group.

In some embodiments, in the photosensitive polymer, R³² of the 31st repeating unit may be bonded to a binding site of a main chain of the 32nd repeating unit. In this case, R³² of the 31st repeating unit is a corresponding divalent group. For example, the photosensitive polymer may include a —[C₂H₃]ₙ—R³²—C— structure. For example, “n” is a natural number in the range from 1 to 100.

In some embodiments, the photosensitive polymer may include a sixth repeating unit represented by Formula 6.

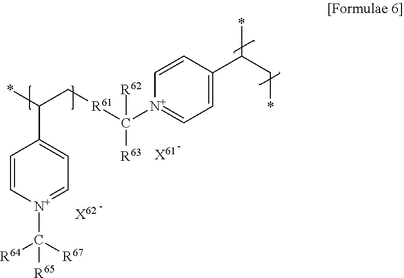

In Formula 6, CR⁶¹ and CR⁶ may each be a functional group convertible to a radical. R⁶¹ may be a substituted or unsubstituted C1 to C30 alkylene group, a substituted or unsubstituted C2 to C30 alkenylene group, a substituted or unsubstituted C1 to C30 alkyleneoxy group, a substituted or unsubstituted C7 to C30 arylalkylene group, a substituted or unsubstituted C2 to C30 acylene group, or a substituted or unsubstituted C7 to C30 divalent alkylbenzenesulfonyl group. R^{M} may be a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, or a substituted or unsubstituted C7 to C30 alkylbenzenesulfonyl group. R⁶², R⁶³, R⁶⁵, and R⁶⁶ may each independently be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C2 to C30 acyl group, a substituted or unsubstituted C7 to C30 alkylbenzenesulfonyl group, a substituted or unsubstituted C6 to C30 aryl group, a substituted or unsubstituted C3 to C30 heteroaryl group, a substituted or unsubstituted C7 to C30 arylalkyl group, or a substituted or unsubstituted phenyl group. X⁶¹ and X⁶² may each be a nonmetallic element or a compound anion. For example, X⁶¹ and X⁶² may each independently be OTs, BF₄, or PF₆. * represents a binding site.

In some embodiments, R⁶¹ and R⁶⁴ may each independently include a functional group that is similar to the examples of R³¹ in Formulae 3 described above, except that R⁶¹ becomes a corresponding divalent group. R⁶¹ and R⁶⁴ may each independently be a substituted C5 to C30 alkyl group, in which at least one hydrogen atom bonded to a carbon atom at position 1, 5, or 6 is substituted with a secondary or higher (e.g., tertiary) substituent or a carbon atom at position 1, 5, or 6 is substituted with a hetero-element-containing group, or R⁶¹ and/or R⁶⁴ may each independently be a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7. A detailed description about the secondary or higher (e.g., tertiary) substituent may refer to that described above in connection with R³¹ in Formula 3.

In some embodiments, the photosensitive polymer may include at least one selected from the first repeating unit, the second repeating unit, the third repeating unit, the 11st repeating unit plus the 12st repeating unit (e.g., the fourth repeating unit), the 21st repeating unit plus the 22st repeating unit (e.g., the fifth repeating unit), and the 31st repeating unit plus the 32st repeating unit (e.g., the sixth repeating unit). For example, the photosensitive polymer may include a combination of the first repeating unit and the second repeating unit, a combination of the first repeating unit and the third repeating unit, a combination of the first repeating unit and the 11st repeating unit plus the 12st repeating unit, or the like.

The solvent, which is included in the photoresist composition, may include an organic solvent. The organic solvent may include, but is not limited to, at least one of ethers, alcohols, glycol ethers, aromatic hydrocarbon compounds, ketones, and esters. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbinol: MIBC), hexanol, 1-methoxy-2-propanol, 1-ethoxy-2-propanol, ethylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxypropionate, ethoxyethoxypropionate, or a combination thereof.

In the photoresist composition according to some embodiments, the solvent may be present in a balance amount except for amounts of main components including the photosensitive polymer and the like. In some embodiments, the solvent may be present in an amount of about 70 wt % to about 99.8 wt % based on the total weight of the photoresist composition or any range therein, but the inventive concept is not limited thereto.

In some embodiments, the photoresist composition may further include a photoinitiator. The photoinitiator may be configured to generate a radical by absorbing light. For example, the photoinitiator may include a photoradical generator (PRG) configured to generate a radical in response to exposure to light. After a photoresist film obtained from the photoresist composition is exposed to light, the photoinitiator may generate a radical by absorbing light in a light-exposed region of the photoresist film. The radical generated from the photoinitiator may react with the first to sixth, 11^{th}, 12^{th}, 21th, 22th, 31th and 32th repeating units of the photosensitive polymer. Therefore, when the photoinitiator is included in the photoresist composition according to some embodiments, a radical chain reaction in the photosensitive polymer, which is described below, may occur due to the radical generated from the photoinitiator.

In the case where the photoinitiator is included in the photoresist composition according to some embodiments, when a photoresist film obtained from the photoresist composition is exposed to light, the photoinitiator may supplement the relatively low reactivity of the photoresist composition, and the sensitivity to light in a light-exposed region of the photoresist film may be adjusted depending on the amount of the photoinitiator. In some embodiments, the photoinitiator may accelerate a radical chain reaction in the photoresist composition by using a radical in the light-exposed region of the photoresist film, thereby inducing a photoreaction to be limitedly performed only in the light-exposed region of the photoresist film.

The PRG may absorb light and generate a radical when exposed to light of one selected from a KrF excimer laser (248 nm), an ArF excimer laser (193 nm), an F₂ excimer laser (157 nm), and an extreme ultraviolet (EUV) laser (13.5 nm), thereby starting the radical chain reaction of the photosensitive polymer that is included in the photoresist composition according to some embodiments. In some embodiments, the PRG may include an acylphosphine oxide-based compound, an oxime ester-based compound, or the like.

The acylphosphine oxide-based compound may include, for example, 2,4,6-trimethylbenzoyl-diphenylphosphine oxide, bis(2,4,6-trimethylbenzoyl)-phenylphosphine oxide, bis(2,6-dimethoxybenzoyl)-(2,4,4-trimethylpentyl)phosphine oxide, or the like.

The oxime ester-based compound may include, for example, 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-9H-carbazol-3-yl]ethanone-1-(O-acetyl)oxime, 1-[9-ethyl-6-[2-methyl-4-[1-(2,2-dimethyl-1,3-dioxolane-4-yl)methyloxy]benzoyl]-9H-carbazol-3-yl]ethanone-1-(O-acetyl)oxime, or the like.

In some embodiments, the PRG may include a commercially available product, such as IRGACURE® 651, IRGACURE® 184, IRGACURE® 1173, IRGACURE® 2959, IRGACURE® 127, IRGACURE® 907, IRGACURE® 369, IRGACURE® 379, IRGACURE® TPO, IRGACURE® 819, IRGACURE® OXE01, IRGACURE® OXE02, IRGACURE® MBF, or IRGACURE® 754 (which is a product model of BASF Co., Ltd.).

The photoresist composition according to the inventive concept may not include the photoinitiator or may include, as the photoinitiator, a single material selected from the PRGs set forth above or at least two materials selected from the PRGs set forth above. When the photoinitiator is included in the photoresist composition according to some embodiments, the photoinitiator may be present in an amount of about 0.02 wt % to about 10 wt % based on the total weight of the photoresist composition, or any range therein, but the inventive concept is not limited thereto.

In some embodiments, when the photoresist composition according to some embodiments includes the PRG as the photoinitiator, the photoresist composition may further include a radical quencher capable of trapping a radical.

In some embodiments, the radical quencher may include a quinone-type free radical or a nitroxide (IUPAC name: aminoxyl) free radical.

The quinone-type free radical may include, but is not limited to, p-benzoquinone, hydroquinone (1,4-dihydroxybenzene), hydroquinone monomethyl ether (4-methoxyphenol), hydroquinone monoethyl ether, hydroquinone monophenyl ether, mono-t-butyl hydroquinone (MTBHQ), di-t-butyl hydroquinone, di-t-amyl hydroquinone, toluhydroquinone, p-benzoquinone dioxime, 2,6-dichloro-1,4-benzoquinone, 2,3,5,6-tetramethyl-1,4-benzoquinone, 2,5-dichloro-3,6-dihydroxy-p-benzoquinone, methyl-p-benzoquinone, 6-anilinoquinoline-5,8-quinone, pyrroloquinoline quinone, 2-allyl-6-methoxybenzo-1,4-quinone, or a combination thereof.

The nitroxide free radical may include, but is not limited to, di-tert-butyl nitroxide (DTBN), 2,2,6,6-tetramethyl-1-peperidine 1-oxyl (TEMPO), oxo TEMPO (4-oxo-2,2,6,6-tetramethyl-1-peperidine 1-oxyl), 1,1,3,3-tetraethylisoindolin-N-oxyl, N-tert-butyl-N-[1-(diethoxyphosphoryl)-2,2-dimethylpropyl]aminoxyl (SG1), N-tert-butyl-N-(2-methyl-1-phenylpropyl) aminoxyl (TIPNO), or a combination thereof.

In some embodiments, the photoresist composition according to some embodiments may further include at least one selected from a leveling agent, a surfactant, a dispersant, a moisture absorbent, and a coupling agent.

The leveling agent is for improving coating flatness when the photoresist composition is coated on a substrate, and a commercially available leveling agent publicly known in the art may be used.

The surfactant may improve the coating uniformity and wettability of the photoresist composition. In some embodiments, the surfactant may include, but is not limited to, a sulfuric acid ester salt, a sulfonic acid salt, phosphoric acid ester, soap, an amine salt, a quaternary ammonium salt, polyethylene glycol, an alkylphenol ethylene oxide adduct, a polyhydric alcohol, a nitrogen-containing vinyl polymer, or a combination thereof. For example, the surfactant may include an alkylbenzene sulfonate, an alkyl pyridinium salt, polyethylene glycol, or a quaternary ammonium salt. When the photoresist composition includes the surfactant, the surfactant may be present in an amount of about 0.001 wt % to about 3 wt % based on the total weight of the photoresist composition, or any range therein.

The dispersant may cause the respective components constituting the photoresist composition to be uniformly dispersed in the photoresist composition. In some embodiments, the dispersant may include, but is not limited to, an epoxy resin, polyvinyl alcohol, polyvinyl butyral, polyvinylpyrrolidone, glucose, sodium dodecyl sulfate, sodium citrate, oleic acid, linoleic acid, or a combination thereof. When the photoresist composition includes the dispersant, the dispersant may be present in an amount of about 0.001 wt % to about 5 wt % based on the total weight of the photoresist composition, or any range therein.

The moisture absorbent may prevent adverse effects due to water in the photoresist composition. In some embodiments, the moisture absorbent may include, but is not limited to, polyoxyethylene nonylphenol ether, polyethylene glycol, polypropylene glycol, polyacrylamide, or a combination thereof. When the photoresist composition includes the moisture absorbent, the moisture absorbent may be present in an amount of about 0.001 wt % to about 10 wt % based on the total weight of the photoresist composition, or any range therein.

The coupling agent may improve adhesion to a feature layer or a lower film when the photoresist composition is coated on the feature layer or the lower film. In some embodiments, the coupling agent may include a silane coupling agent. The silane coupling agent may include, but is not limited to, vinyltrimethoxysilane, vinyltriethoxysilane, vinyltrichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be present in an amount of about 0.001 wt % to about 5 wt % based on the total weight of the photoresist composition, or any range therein.

When a photoresist film obtained from the photoresist composition including the photosensitive polymer according to some embodiments is exposed to light, the photoresist composition may absorb light, and the functional group convertible to a radical may be dissociated from the pyridinium salt of the photosensitive polymer. Thus, in some embodiments, the pyridinium salt of the photosensitive polymer may be converted into a pyridine group, and thereby substituted with a pyridine group, and a change in polarity of the photosensitive polymer may be induced.

A process in which a radical is generated from the functional group convertible (e.g., capable of being converted) to a radical may be described as follows. Secondary electrons may be generated by exposing the photoresist film to light, and an N—O bond of —N—OR¹¹ in the first repeating unit, an N—N bond of —N—N(R²¹)(R²²) in the second repeating unit, or an N—C bond of —N—C(R³¹)(R³²)(R³³) in the third repeating unit, in the photosensitive polymer of the photoresist film exposed to light, may be decomposed due to the secondary electrons. Alternatively, radicals may be generated by the photoinitiator of the photoresist composition, and the N—O bond of —N—OR¹¹ in the first repeating unit, the N—N bond of —N—N(R²¹)(R²²) in the second repeating unit, or the N—C bond of —N—C(R³¹)(R³²)(R³³) in the third repeating unit, in the photosensitive polymer of the photoresist film exposed to light, may be decomposed due to the radicals.

In some embodiments, due to the decomposition of the N—O bond of —N—OR¹¹ in the first repeating unit, the N—N bond of —N—N(R²¹)(R²²) in the second repeating unit, or the N—C bond of —N—C(R³¹)(R³²)(R³³) in the third repeating unit, radicals each having an unpaired electron may be generated. For example, a radical including HO—R^{11·} may be generated by the decomposition of the N—O bond of —N—OR¹¹ in the first repeating unit, a radical including HN—R²¹(R²²)· may be generated by the decomposition of the N—N bond of —N—N(R²¹)(R²²) in the second repeating unit, and a radical including HC—R³¹(R³²)(R³³)· may be generated by the decomposition of the N—C bond of —N—C(R³¹)(R³²)(R³³) in the third repeating unit. As used herein, the symbol “·” refers to an unpaired electron. Here, when R¹¹, R²¹, or R³¹ includes a functional group capable of performing a 1,5-hydrogen atom transfer reaction or an intramolecular cyclization reaction, a radical can be generated by decomposition of a bond between the oxygen atom, the nitrogen atom or the carbon atom of the functional group convertible to the radical and the nitrogen atom of the pyridinium salt.

Next, in the vicinity of the first repeating unit, the second repeating unit, or the third repeating unit, from which the functional group convertible to a radical is dissociated, a radical may be bonded to an ortho position of a pyridinium salt that is included in the first repeating unit, the second repeating unit, or the third repeating unit, to which the functional group convertible to a radical is bonded, and due to the bonding of the radical, the functional group convertible to a radical may be dissociated from the pyridinium salt to generate a new radical. Thus, in some embodiments, a chain of decomposition reactions of the photosensitive polymer may occur.

For example, in some embodiments, HO—R^{11·} may be bonded to the ortho position of the pyridinium salt of the first repeating unit to decompose the N—O bond of —N—OR¹¹, thereby generating a radical including HO—R^{11·} again, HN—R²¹(R²²)· may be bonded to the ortho position of the pyridinium salt of the second repeating unit to decompose the N—N bond of —N—N(R²¹)(R²²), thereby generating a radical including HN—R²¹(R²²)· again, and HC—R³¹(R³²)(R³³)· may be bonded to the ortho position of the pyridinium salt of the third repeating unit to decompose the N—C bond of —N—C(R³¹)(R³²)(R³³), thereby generating a radical including HC—R³¹(R³²)(R³³)· again. Therefore, in some embodiments, a chain of decomposition reactions of the N—O bond of —N—OR¹¹ in the first repeating unit, the N—N bond of —N—N(R²¹)(R²²) in the second repeating unit, or the N—C bond of —N—C(R³¹)(R³²)(R³³) in the third repeating unit may occur.

For example, in some embodiments, when a photoresist film obtained from the photoresist composition including the photosensitive polymer, which includes one of the structures of Formulae 1 described above, is exposed to light, a chain of decomposition reactions of the N—O bond of —N—OR¹¹ in the first repeating unit may be represented by Reaction Formula 1 shown below.

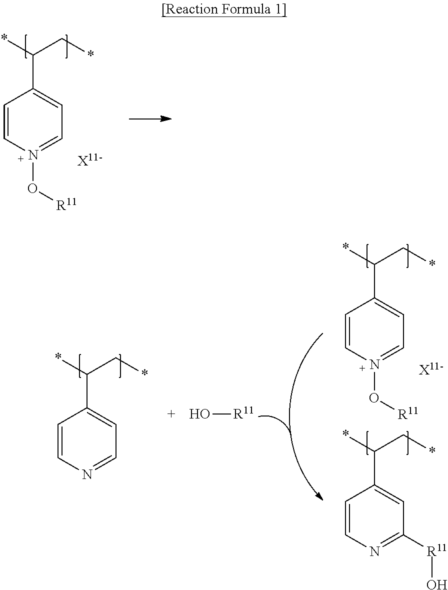

In some embodiments, due to the chain of decomposition reactions of the photosensitive polymer by the radical, the first repeating unit in the photosensitive polymer may be converted from a structure including a pyridinium salt into a structure in which —R¹¹OH is bonded to an ortho position of a pyridine group, into a structure in which a material selected from PRGs added by the photoinitiator is bonded to an ortho position of a pyridine group, or into a structure including a pyridine group. In addition, the second repeating unit may be converted from a structure including a pyridinium salt into a structure in which —R²¹—N(R²²)(H) is bonded to an ortho position of a pyridine group, into a structure in which a material selected from PRGs added by the photoinitiator is bonded to an ortho position of a pyridine group, or into a structure including a pyridine group. In addition, the third repeating unit may be converted from a structure including a pyridinium salt into a structure in which —R³¹C(R³²)(R³³) is bonded to an ortho position of a pyridine group, into a structure in which a material selected from PRGs added by the photoinitiator is bonded to an ortho position of a pyridine group, or into a structure including a pyridine group.

For example, in some embodiments, when a photoresist film obtained from the photoresist composition including the photosensitive polymer, which includes one of the structures of Formulae 1 described above, is exposed to light, a reaction as in Reaction Formula 2 shown below may occur, and the first repeating unit in Formula 1 may be converted to include a structure shown as the resulting product of Reaction Formula 2.

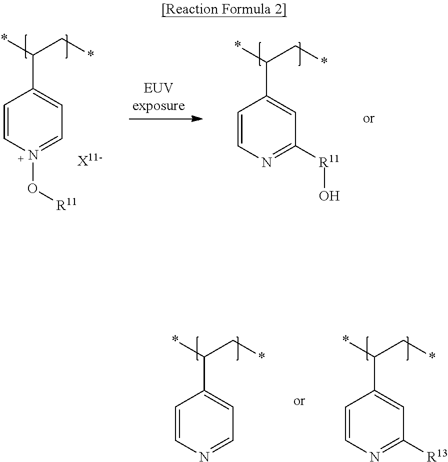

In Reaction Formula 2, R¹³ may be, for example, a material selected as the photoinitiator from the PRGs described above.

For example, in some embodiments, when a photoresist film obtained from the photoresist composition including the photosensitive polymer, which includes one of the structures of Formulae 2 described above, is exposed to light, a reaction as in Reaction Formula 3 shown below may occur, and the second repeating unit in Formula 2 may be converted to include a structure shown as the resulting product of Reaction Formula 3.

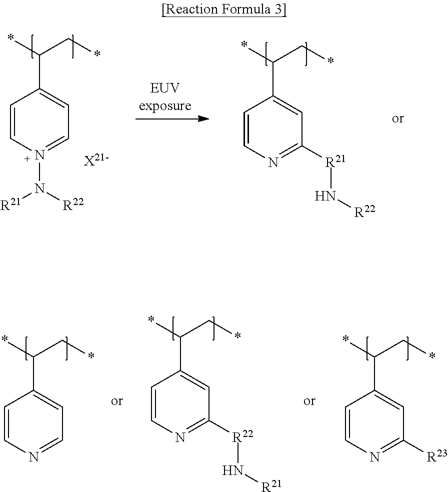

In Reaction Formula 3, R²³ may be, for example, a material selected as the photoinitiator from the PRGs described above.

The photoresist composition according to some embodiments may include a photosensitive polymer including a functional group convertible to a radical. In a light-exposure process, by a decomposition reaction of the photosensitive polymer and a radical generated due to the decomposition reaction of the photosensitive polymer and an optional radical generated the photoinitiator, a chain of decomposition reactions of the photosensitive polymer may be induced. Although the photosensitive polymer includes a pyridinium salt, because the pyridinium salt of the photosensitive polymer is substituted with a pyridine group due to the dissociation of the functional group convertible to a radical, the photosensitive polymer may be converted to be soluble in a developer.

Here, in some embodiments, due to the high reactivity and short lifespan of a radical, because the photosensitive polymer in a non-light-exposed region may undergo a relatively small number of decomposition reactions that may be caused by the radical permeating into the non-light-exposed region, the light-exposure sensitivity in a light-exposed region of a photoresist film may improve. Therefore, in some embodiments, excellent resolution and improved sensitivity may be provided in a photolithography process, and a critical dimension (CD) distribution of a pattern obtained by the photolithography process may be prevented from deteriorating, thereby improving the dimensional precision of the pattern intended to be formed.

Alternatively, in some embodiments, in exposing the photoresist film to light, when the photosensitive polymer includes at least one of the fourth to sixth repeating units, an N—O bond of —N—OR⁴¹— in the fourth repeating unit, an N—N bond of —N—N(R¹)(R⁵²)— in the fifth repeating unit, or an N—C bond of —N—C(R⁶¹)(R⁶²)(R⁶³)— in the sixth repeating unit may be decomposed.

An exemplary process, in which the functional group convertible to a radical is dissociated from the pyridinium salt of the photosensitive polymer and a radical is generated from the functional group convertible to a radical, thereby decomposing the main chain of the photosensitive polymer, may be described as follows. In some embodiments, secondary electrons may be generated by exposing the photoresist film to light, and the N—O bond of —N—OR⁴¹— in the fourth repeating unit, the N—N bond of —N—N(R⁵¹)(R⁵²)— in the fifth repeating unit, or the N—C bond of —N—C(R⁶¹)(R⁶²)(R⁶³)— in the sixth repeating unit, in the photosensitive polymer of the photoresist film exposed to light, may be decomposed due to the secondary electrons. Alternatively, radicals may be generated by the photoinitiator of the photoresist composition, and the N—O bond of —N—OR⁴¹— in the fourth repeating unit, the N—N bond of —N—N(R⁵¹)(R⁵²)— in the fifth repeating unit, or the N—C bond of —N—C(R⁶¹)(R⁶²)(R⁶³)— in the sixth repeating unit, in the photosensitive polymer of the photoresist film exposed to light, may be decomposed due to the radicals.

For example, in some embodiments, when a photoresist film obtained from the photoresist composition including the photosensitive polymer, which includes the structure of Formula 4 described above, is exposed to light, a reaction as in Reaction Formula 4 shown below may occur, and the fourth repeating unit in Formula 4 may be converted to include a structure shown as the resulting product of Reaction Formula 4.

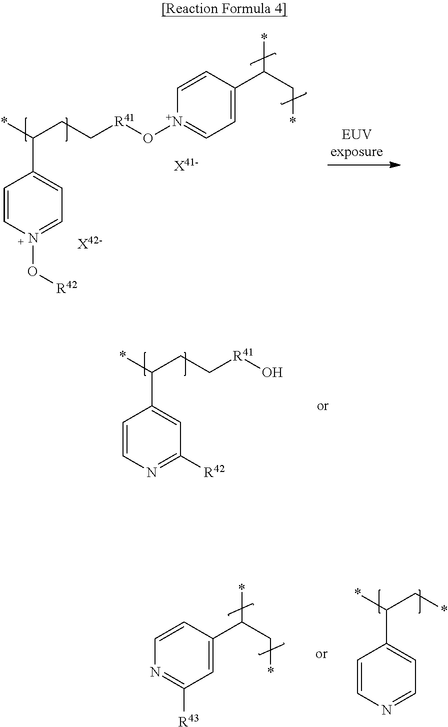

In Reaction Formula 4, R⁴³ may be, for example, a material selected as the photoinitiator from the PRGs described above.

When the photoresist composition according to some embodiments includes a photosensitive polymer having an MCS structure, because the main chain of the photosensitive polymer is cut by a light-exposure process, the molecular weight of the photosensitive polymer may be reduced, and thus, the light-exposure sensitivity in the light-exposed region of the photoresist film may improve. Therefore, in some embodiments, excellent resolution and improved sensitivity may be provided in a photolithography process, and a CD distribution of a pattern obtained by the photolithography process may be prevented from deteriorating, thereby improving the dimensional precision of the pattern intended to be formed.

The photosensitive polymer, which is included in the photoresist composition according to some embodiments, may be synthesized by a synthesis method described below. However, the synthesis method of the photosensitive polymer, which is described below, is only an example, and the photosensitive polymer may be synthesized by various synthesis methods.

In some embodiments, the photosensitive polymer including the first repeating unit may be synthesized through a reaction as in Synthetic Formula 1 shown below.

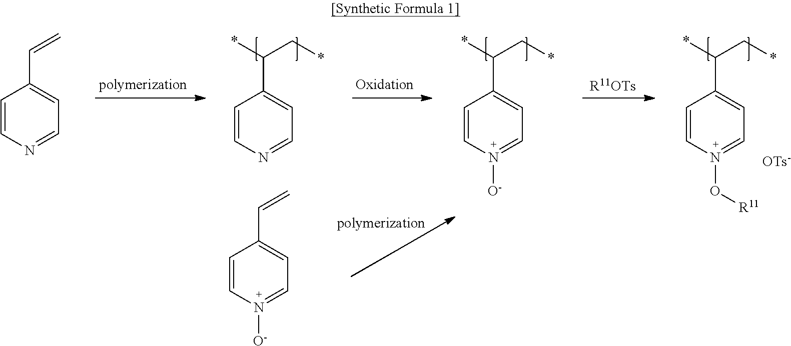

Referring to Synthetic Formula 1, in some embodiments, poly(4-vinylpyridine) may be synthesized through a polymerization reaction of 4-vinylpyridine (that is, 4-ethenylpyridine), and then, an oxidation reaction of poly(4-vinylpyridine) and an addition reaction of R¹¹—OTs may be sequentially performed in the stated order, thereby synthesizing the photosensitive polymer including the first repeating unit. In some embodiments, the photosensitive polymer including the first repeating unit may be synthesized by using 4-vinylpyridine-N-oxide as a monomer and adding R¹¹—OTs.

In some embodiments, the photosensitive polymer including the second repeating unit may be synthesized through a reaction as in Synthetic Formula 2 shown below.

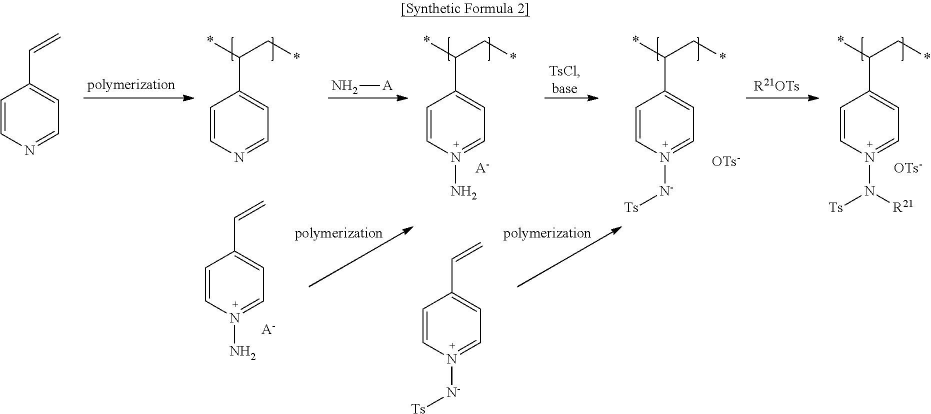

In Synthetic Formula 2, A may be a nonmetallic element or a compound anion. In some embodiments, poly(4-vinylpyridine) may be synthesized through a polymerization reaction of 4-vinylpyridine (that is, 4-ethenylpyridine), and then, NH₂-A (where A is a nonmetallic element or a compound anion), both TsCl and a base, and R²¹OTs may be sequentially added in the stated order, thereby synthesizing the photosensitive polymer including the second repeating unit. In some embodiments, the photosensitive polymer including the second repeating unit may be synthesized by using NH₂—C₅H₄N—CH═CH₂ as a monomer and sequentially adding both TsCl and a base and R²¹OTs in the stated order, or by using Ts-N—C₅H₄N—CH═CH₂ as a monomer and adding R²¹OTs.

In some embodiments, the photosensitive polymer including the third repeating unit may be synthesized through a reaction as in Synthetic Formula 3 shown below.

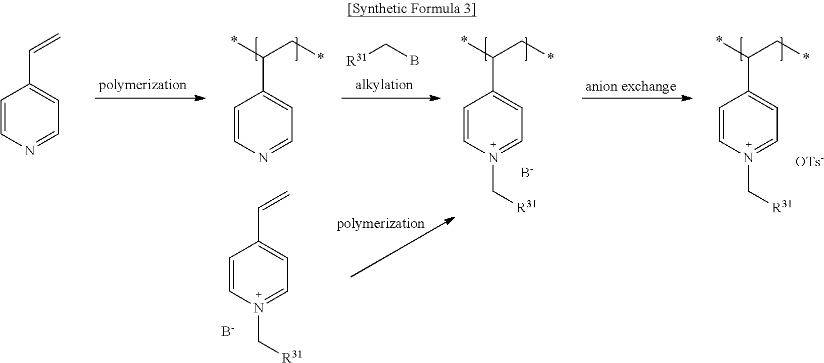

In Synthetic Formula 3, B may be a nonmetallic element or a compound anion. In some embodiments, poly(4-vinylpyridine) may be synthesized through a polymerization reaction of 4-vinylpyridine (that is, 4-ethenylpyridine), and then, an alkylation reaction and an anion exchange reaction may be sequentially performed in the stated order, thereby synthesizing the photosensitive polymer including the third repeating unit. Alternatively, in some embodiments, the photosensitive polymer including the third repeating unit may be synthesized by using R³¹—CH₂—C₅H₄N—CH═CH₂ as a monomer and performing an anion exchange reaction.

In some embodiments, the photosensitive polymer including the fourth repeating unit may be synthesized through a reaction as in Synthetic Formula 4 shown below.

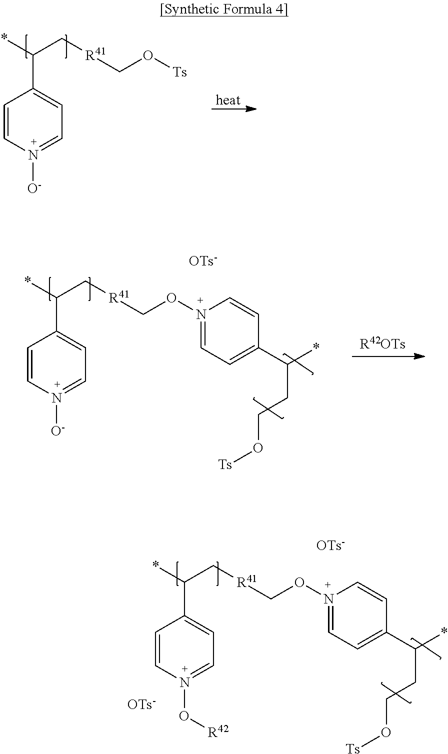

As shown in Synthetic Formula 4, in some embodiments, [CH₂C₅H₄NO]ₙ—R⁴¹—O-Ts may be heated, for example, to 80° C. to 90° C., followed by adding R⁴²—OTs, thereby synthesizing the photosensitive polymer including the fourth repeating unit.

Next, a method of manufacturing an integrated circuit device by using the photoresist composition according to some embodiments is described by taking a specific example.

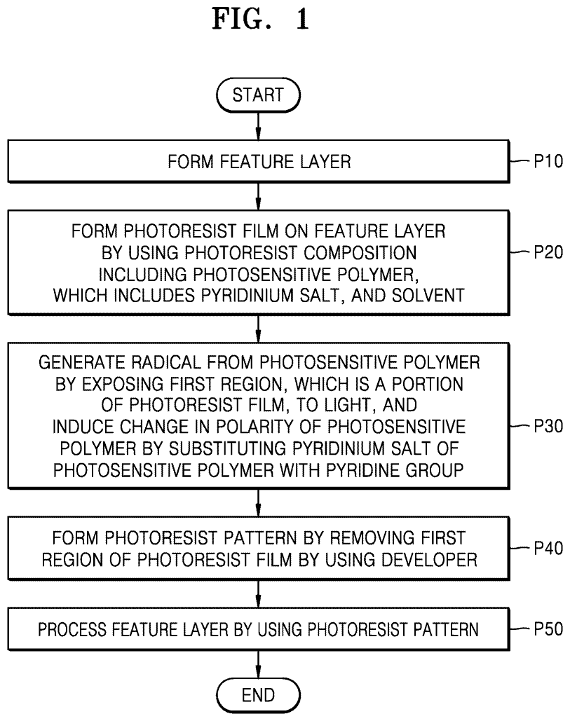

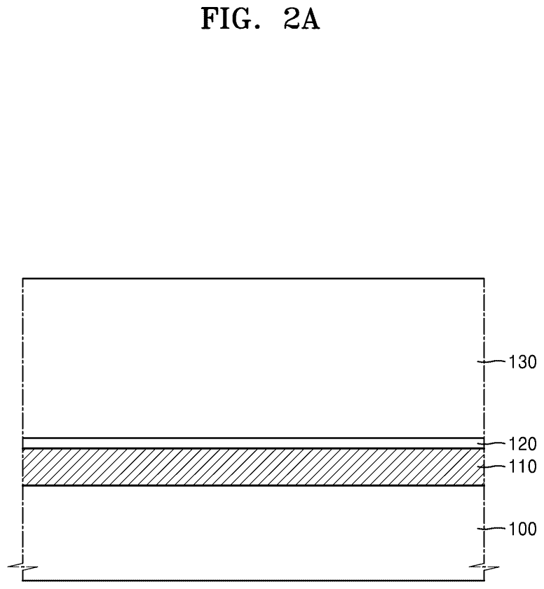

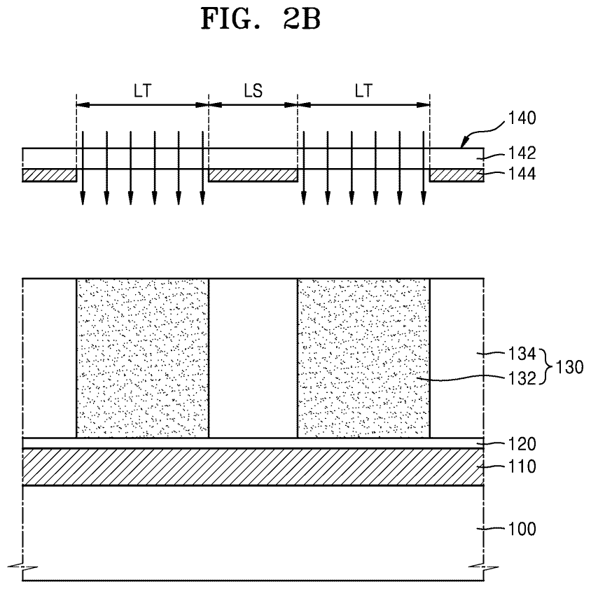

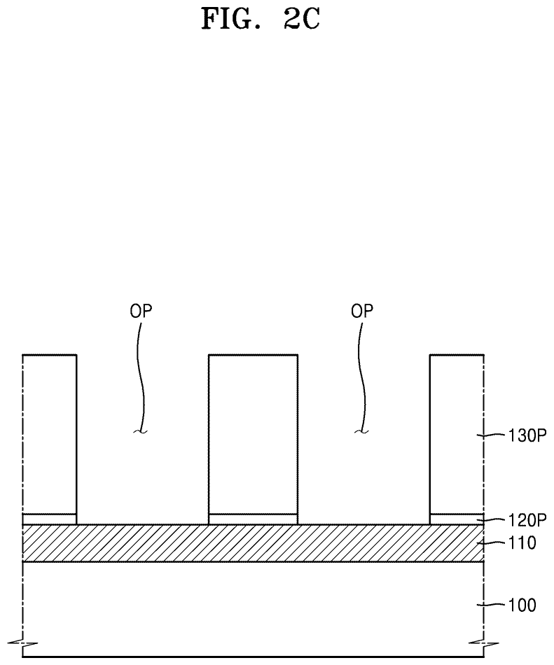

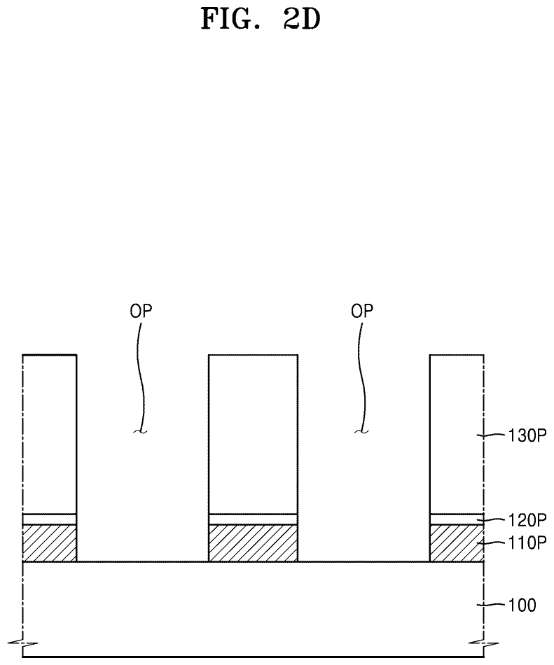

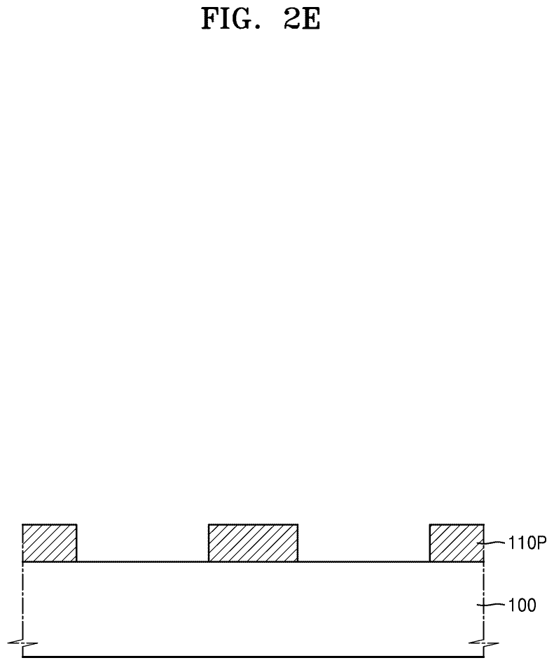

FIG. 1 is a flowchart illustrating a method of manufacturing an integrated circuit device, according to some embodiments. FIGS. 2A to 2E are cross-sectional views respectively illustrating a sequence of processes of a method of manufacturing an integrated circuit device, according to some embodiments.

Referring to FIGS. 1 and 2A, in process P10, a feature layer 110 may be formed on a substrate 100. Next, in process P20, a photoresist film 130 may be formed on the feature layer 110 by using the photoresist composition according to some embodiments. A detailed configuration of the photoresist composition is the same as described above.

The substrate 100 may include a semiconductor substrate. The feature layer 110 may include an insulating film, a conductive film, or a semiconductor film. For example, the feature layer 110 may include, but is not limited to, a metal, an alloy, a metal carbide, a nitride (e.g., a metal nitride), an oxynitride (e.g., a metal oxynitride), a metal oxycarbide, a semiconductor, polysilicon, an oxide, or a combination thereof.

In some embodiments, as shown in FIG. 2A, before the photoresist film 130 is formed on the feature layer 110, a lower film 120 may be formed on the feature layer 110. In this case, the photoresist film 130 may be formed on the lower film 120. The lower film 120 may prevent the photoresist film 130 from being adversely affected by the feature layer 110 under the photoresist film 130. In some embodiments, the lower film 120 may include an organic or inorganic anti-reflective coating (ARC) material for KrF excimer lasers, ArF excimer lasers, EUV lasers, or any other light sources. In some embodiments, the lower film 120 may include a bottom anti-reflective coating (BARC) film or a developable bottom anti-reflective coating (DBARC) film. In some embodiments, the lower film 120 may include an organic component having a light absorption structure. The light absorption structure may include, for example, a hydrocarbon compound having a structure in which one or more benzene rings are fused. The lower film 120 may have, but is not limited to, a thickness of about 1 nm to about 100 nm. In some embodiments, the lower film 120 may be omitted.

To form the photoresist film 130, the photoresist composition according to some embodiments may be coated on the lower film 120 and then heat treated. The coating may be performed by a method, such as spin coating, spray coating, dip coating, or the like. A process of heat-treating the photoresist composition may be performed at a temperature of about 80° C. to about 300° C. for about 10 seconds to about 100 seconds, but the inventive concept is not limited thereto. The thickness of the photoresist film 130 may be tens to hundreds of times the thickness of the lower film 120. The photoresist film 130 may have, but is not limited to, a thickness of about 10 nm to about 1 μm.

Referring to FIGS. 1 and 2B, in process P30, a first region 132, which is a portion of the photoresist film 130, may be exposed to light. As a result, in a photosensitive polymer that is included in the photoresist film 130 in the first region 132, a radical generation reaction and a decomposition reaction of the photosensitive polymer, as described above, may be induced.

For example, when the first region 132, which is a portion of the photoresist film 130, is exposed to light according to process P30 of FIG. 1, a radical may be generated from a functional group that is convertible to a radical and bonded to a pyridinium salt of the photosensitive polymer in the first region 132, and the functional group convertible to a radical may be dissociated from the pyridinium salt of the photosensitive polymer, whereby the pyridinium salt of the photosensitive polymer may be substituted with a pyridine group and a change in polarity of the photosensitive polymer may be induced. Because a second region 134, which is a portion of the photoresist film 130, is not exposed to light, the photosensitive polymer in the second region 134 may be maintained in a structure including the pyridinium salt. Therefore, the difference in solubility in a developer between the first region 132 and the second region 134 of the photoresist film 130 may be increased.

Due to the high reactivity and short lifespan of the radical generated by the dissociation of the functional group, which is convertible to a radical, of the photosensitive polymer, the photosensitive polymer in a non-light-exposed region may undergo a relatively small number of decomposition reactions that may be caused by the radical permeating into the non-light-exposed region, and thus, the light-exposure sensitivity in the light-exposed region of the photoresist film 130 may improve. Therefore, excellent resolution and improved sensitivity may be provided in a photolithography process, and a CD distribution of a pattern obtained by the photolithography process may be prevented from deteriorating, thereby improving the dimensional precision of the pattern intended to be formed.

In some embodiments, in the case where a photoinitiator is included in the photoresist film 130, when the first region 132, which is a portion of the photoresist film 130, is exposed to light according to process P30 of FIG. 1, a radical may be generated from the photoinitiator in the first region 132. The photoinitiator may include a PRG configured to generate a radical in response to light. Therefore, while the first region 132 of the photoresist film 130 is being exposed to light according to process P30 of FIG. 1, the photoinitiator of the photoresist film 130 in the first region 132 may generate a radical by absorbing light, which leads to a dissociation of the functional group, which is convertible to a radical, of the photosensitive polymer from the pyridinium salt of the photosensitive polymer, so that the pyridinium salt is converted into a pyridine group.

In some embodiments, to expose the first region 132 of the photoresist film 130 to light, a photomask 140, which has a plurality of light shielding areas LS and a plurality of light transmitting areas LT, may be aligned at a certain position over the photoresist film 130, and the first region 132 of the photoresist film 130 may be exposed to light through the plurality of light transmitting areas LT of the photomask 140. To expose the first region 132 of the photoresist film 130, a KrF excimer laser (248 nm) to light, an ArF excimer laser (193 nm), an F₂ excimer laser (157 nm), or an EUV laser (13.5 nm) may be used.

In some embodiments, the photomask 140 may include a transparent substrate 142, and a plurality of light shielding patterns 144 formed in the plurality of light shielding areas LS on the transparent substrate 142. In some embodiments, the transparent substrate 142 may include quartz. In some embodiments, the plurality of light shielding patterns 144 may include chromium (Cr). The plurality of light transmitting areas LT may be defined by the plurality of light shielding patterns 144. According to some embodiments of the inventive concept, to expose the first region 132 of the photoresist film 130 to light, a reflective photomask (not shown) for EUV exposure may be used instead of the photomask 140.

Next, a bake process may be performed by applying heat to the photoresist film 130 including the first region 132 that is exposed to light.

The bake process may be performed at a temperature of about 50° C. to about 400° C. or any range therein, for about 10 seconds to about 150 seconds, or any range therein. For example, the bake process may be performed at a temperature of about 150° C. to about 250° C. for about 60 seconds to about 120 seconds, but the inventive concept is not limited thereto. In some embodiments, the bake process may be omitted depending on processes.

Referring to FIGS. 1 and 2C, in process P40, the first region 132 of the photoresist film 130 may be removed by developing the photoresist film 130 by using a developer. As a result, a photoresist pattern 130P including the second region 134 of the photoresist film 130, which is not exposed to light, may be formed.

The photoresist pattern 130P may include a plurality of openings OP. After the photoresist pattern 130P is formed, a lower pattern 120P may be formed by removing portions of the lower film 120, which are exposed by the plurality of openings OP.

In some embodiments, the development of the photoresist film 130 may be performed by a positive-tone development (PTD) process.

In some embodiments, to develop the photoresist film 130, a developer including an organic solvent may be used. For example, the developer may include, but is not limited to, ketones, such as methyl ethyl ketone, acetone, cyclohexanone, and 2-heptanone; alcohols, such as 4-methyl-2-propanol, 1-butanol, isopropanol, 1-propanol, and methanol; esters, such as propylene glycol monomethyl ether acetate, ethyl acetate, ethyl lactate, n-butyl acetate, and butyrolactone; aromatic compounds, such as benzene, xylene, and toluene; or combinations thereof. In some embodiments, to develop the photoresist film 130, an alkaline developer may be used. In some embodiments, the alkaline developer may include tetramethylammonium hydroxide (TMAH) aqueous solution, which may comprises, for example, 2.38 wt % of TMAH.

As described with reference to FIG. 2B, as the difference in solubility in the developer between the light-exposed first region 132 and the non-light-exposed second region 134 in the photoresist film 130 is increased, while the first region 132 is being removed by developing the photoresist film 130, the second region 134 may remain as it is without being removed. Therefore, after the photoresist film 130 is developed, residual defects, such as a footing phenomenon, may not occur, and a vertical sidewall profile of the photoresist pattern 130P may be obtained. As such, by improving the sidewall profile of the photoresist pattern 130P, in some embodiments, a CD of an intended processing region in the feature layer 110 may be precisely controlled when the feature layer 110 is processed by using the photoresist pattern 130P.

In some embodiments, after the photoresist pattern 130P is formed by developing the photoresist film 130, a process of performing hard bake on the obtained resulting product may be further performed. Through the hard bake process, unnecessary materials, such as the developer remaining on the resulting product in which the photoresist pattern 130P is formed, may be removed.

The hard bake process may be performed at a temperature of about 50° C. to about 400° C., or any range therein for about 10 seconds to about 150 seconds, or any range therein. For example, the hard bake process may be performed at a temperature of about 150° C. to about 250° C., or any range therein for about 60 seconds to about 120 seconds, or any range therein, but the inventive concept is not limited thereto.

Referring to FIGS. 1 and 2D, in process P50, in the resulting product of FIG. 2C, the feature layer 110 may be processed by using the photoresist pattern 130P.

To process the feature layer 110, various processes, such as a process of etching the feature layer 110 exposed by an opening OP of the photoresist pattern 130P, a process of implanting impurity ions into the feature layer 110, a process of forming an additional film on the feature layer 110 through the opening OP, and a process of modifying a portion of the feature layer 110 through the opening OP, may be performed. Although FIG. 2D illustrates, as an example of a process of processing the feature layer 110, an example of forming a feature pattern 110P by etching the feature layer 110 exposed by the opening OP, the inventive concept is not limited thereto.

In some embodiments, the process of forming the feature layer 110 may be omitted from the process described with reference to FIG. 2A, and in this case, instead of the process P50 of FIG. 1 and the process described with reference to FIG. 2D, the substrate 100 may be processed by using the photoresist pattern 130P. For example, various processes, such as a process of etching a portion of the substrate 100 by using the photoresist pattern 130P, a process of implanting impurity ions into a portion of the substrate 100, a process of forming an additional film on the substrate 100 through the opening OP, and a process of modifying a portion of the substrate 100 through the opening OP, may be performed.

Referring to FIG. 2E, in the resulting product of FIG. 2D, the photoresist pattern 130P and the lower pattern 120P, which remain on the feature pattern 110P, may be removed. To remove the photoresist pattern 130P and the lower pattern 120P, ashing and strip processes may be used.

According to the method of manufacturing an integrated circuit device, which is described with reference to FIGS. 1 and 2A to 2E, the difference in solubility in a developer between a light-exposed region and a non-light-exposed region of the photoresist film 130, which is obtained by using the photoresist composition according to the inventive concept, may be increased, and a CD distribution in the photoresist pattern 130P may improve. Therefore, when a subsequent process is performed on the feature layer 110 and/or the substrate 100 by using the photoresist pattern 130P, CDs of processing regions or patterns intended to be formed in the feature layer 110 and/or the substrate 100 may be precisely controlled, thereby improving dimensional precision. In addition, a CD distribution of patterns intended to be implemented on the substrate 100 may be uniformly controlled, and the productivity of a manufacturing process of an integrated circuit device may improve.

While the inventive concept has been particularly shown and described with reference to embodiments thereof, it will be understood that various changes in form and details may be made therein without departing from the spirit and scope of the following claims.

What is claimed is:

1. A photoresist composition comprising:
a photosensitive polymer; and
a solvent,
wherein the photosensitive polymer comprises a pyridinium salt and a functional group convertible to a radical and bonded to the pyridinium salt, and
the functional group convertible to the radical comprises an oxygen atom, a nitrogen atom or a carbon atom bonded to a nitrogen atom of the pyridinium salt, and is able to generate the radical by decomposition of a bond between the oxygen atom, the nitrogen atom or the carbon atom of the functional group convertible to the radical and the nitrogen atom of the pyridinium salt.

2. The photoresist composition of claim 1, wherein the photosensitive polymer comprises a first repeating unit represented by one of the structures of Formulae 1: 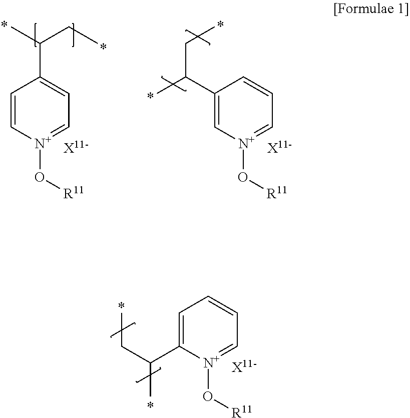
wherein, in Formulae 1, R¹¹ is a substituted or unsubstituted C1 to C30 alkyl group, a substituted or unsubstituted C2 to C30 alkenyl group, or a substituted or unsubstituted C7 to C30 arylalkyl group,
X¹¹⁻ is a nonmetallic element or a compound anion, and
* represents a binding site.

3. The photoresist composition of claim 2, wherein R¹¹ is a substituted C5 to C30 alkyl group, in which at least one hydrogen atom bonded to a carbon atom at position 1, 5, or 6 is substituted with a secondary or tertiary substituent or a carbon atom at position 1, 5, or 6 is substituted with a hetero-element-containing group.

4. The photoresist composition of claim 2, wherein R¹¹ is a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7.

5. The photoresist composition of claim 1, wherein the photosensitive polymer comprises a first repeating unit represented by one of the structures of Formulae 1-1: 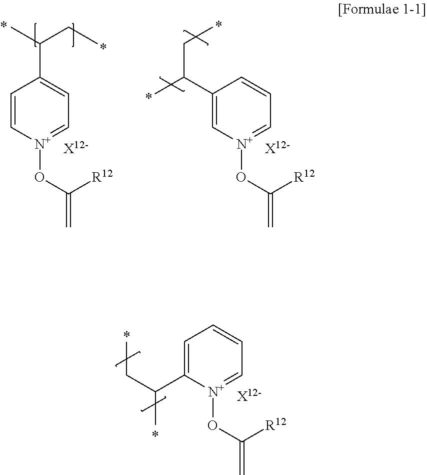
wherein, in Formulae 1-1, R¹² is hydrogen, a C1 to C30 alkyl group, a C2 to C30 alkenyl group, a C2 to C30 alkynyl group, a C3 to C30 cycloalkyl group, a C1 to C30 alkoxy group, a C6 to C30 aryl group, a C3 to C30 heteroaryl group, a C7 to C30 arylalkyl group, or a phenyl group,
X¹²⁻ is a nonmetallic element or a compound anion, and
* represents a binding site.

6. The photoresist composition of claim 1, wherein the photosensitive polymer comprises a second repeating unit represented by one of the structures of Formulae 2: 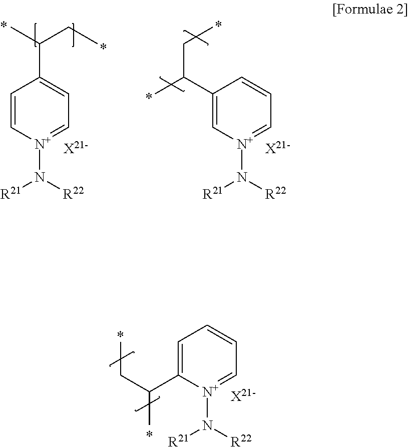
wherein, in Formulae 2, R²¹ is a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, or a substituted or unsubstituted C7 to C30 alkylbenzenesulfonyl group,
R²² is hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C2 to C30 acyl group, a substituted or unsubstituted C7 to C30 alkylbenzenesulfonyl group, a substituted or unsubstituted C6 to C30 aryl group, a substituted or unsubstituted C3 to C30 heteroaryl group, a substituted or unsubstituted C7 to C30 arylalkyl group, or a substituted or unsubstituted phenyl group,
X²¹⁻ is a nonmetallic element or a compound anion, and
* represents a binding site.

7. The photoresist composition of claim 6, wherein R²¹ is a substituted C5 to C30 alkyl group, in which at least one hydrogen atom bonded to a carbon atom at position 1, 5, or 6 is substituted with a secondary or tertiary substituent or a carbon atom at position 1, 5, or 6 is substituted with a hetero-element-containing group.

8. The photoresist composition of claim 6, wherein R²¹ is a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7.

9. The photoresist composition of claim 1, wherein the photosensitive polymer comprises a third repeating unit represented by one of the structures of Formulae 3: 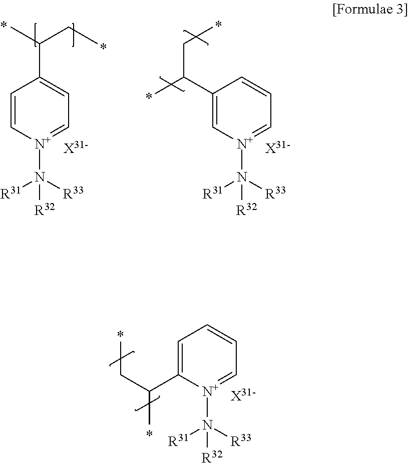
wherein, in Formulae 3, R³¹ is a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, or a substituted or unsubstituted C7 to C30 alkylbenzenesulfonyl group,
R³² and R³³ are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C2 to C30 acyl group, a substituted or unsubstituted C7 to C30 alkylbenzenesulfonyl group, a substituted or unsubstituted C6 to C30 aryl group, a substituted or unsubstituted C3 to C30 heteroaryl group, a substituted or unsubstituted C7 to C30 arylalkyl group, or a substituted or unsubstituted phenyl group,
X³¹⁻ is a nonmetallic element or a compound anion, and
* represents a binding site.

10. The photoresist composition of claim 9, wherein R³¹ is a substituted C5 to C30 alkyl group, in which at least one hydrogen atom bonded to a carbon atom at position 1, 5, or 6 is substituted with a secondary or tertiary substituent or a carbon atom at position 1, 5, or 6 is substituted with a hetero-element-containing group.

11. The photoresist composition of claim 9, wherein R³¹ is a substituted or unsubstituted C5 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7.

12. A photoresist composition comprising:
a photosensitive polymer; and
a solvent,
wherein the photosensitive polymer comprises a pyridinium salt and a functional group convertible to a radical and bonded to the pyridinium salt, the functional group convertible to the radical is comprised in a main chain of the photosensitive polymer.

13. The photoresist composition of claim 12, wherein the photosensitive polymer comprises an 11th repeating unit and a 12th repeating unit, which are each represented by one of the structures of Formulae 1, and
in Formulae 1, R¹¹ of the 11th repeating unit is bonded to a binding site of a main chain of the 12th repeating unit: 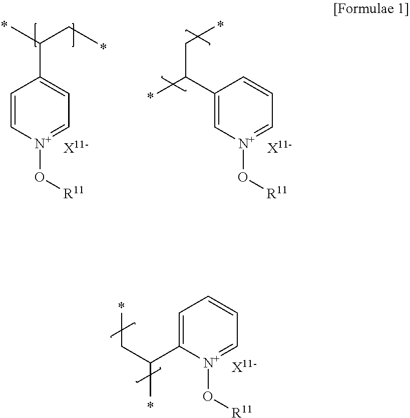
wherein, in Formulae 1,
R¹¹ of the 12th repeating unit is a substituted or unsubstituted C1 to C30 alkyl group, a substituted or unsubstituted C2 to C30 alkenyl group, or a substituted or unsubstituted C7 to C30 arylalkyl group,
R¹¹ of the 11th repeating unit is a substituted or unsubstituted C1 to C30 alkylene group, a substituted or unsubstituted C2 to C30 alkenylene group, or a substituted or unsubstituted C7 to C30 arylalkylene group,
X¹¹⁻ is a nonmetallic element or a compound anion, and
* represents the binding site.

14. The photoresist composition of claim 12, wherein the photosensitive polymer comprises a 21st repeating unit and a 22nd repeating unit, which are each represented by one of the structures of Formulae 2, and
in Formulae 2, R²¹ of the 21st repeating unit is bonded to a binding site of a main chain of the 22nd repeating unit: 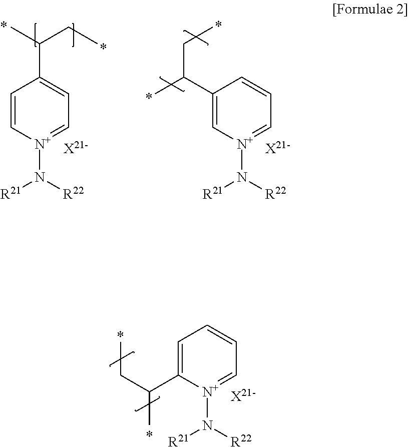
wherein, in Formulae 2,
R²¹ of the 22nd repeating unit is a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, or a substituted or unsubstituted C7 to C30 alkylbenzenesulfonyl group,
R²¹ of the 21nd repeating unit is a substituted or unsubstituted C1 to C30 alkylene group, a substituted or unsubstituted C2 to C30 alkenylene group, a substituted or unsubstituted C1 to C30 alkyleneoxy group, a substituted or unsubstituted C7 to C30 arylalkylene group, a substituted or unsubstituted C2 to C30 acylene group, or a substituted or unsubstituted C7 to C30 divalent alkylbenzenesulfonyl group,
R²² is hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C2 to C30 acyl group, a substituted or unsubstituted C7 to C30 alkylbenzenesulfonyl group, a substituted or unsubstituted C6 to C30 aryl group, a substituted or unsubstituted C3 to C30 heteroaryl group, a substituted or unsubstituted C7 to C30 arylalkyl group, or a substituted or unsubstituted phenyl group,
X²¹⁻ is a nonmetallic element or a compound anion, and
* represents the binding site.

15. The photoresist composition of claim 12, wherein the photosensitive polymer comprises a 31st repeating unit and a 32nd repeating unit, which are each represented by one of the structures of Formulae 3, and
in Formulae 3, R³¹ of the 31st repeating unit is bonded to a binding site of a main chain of the 32nd repeating unit: 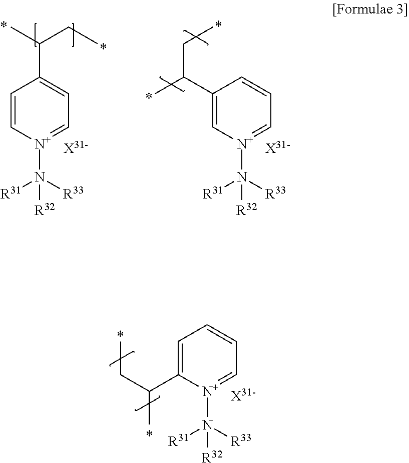
wherein, in Formulae 3, R³¹ of the 32nd repeating unit is a substituted or unsubstituted C1 to C30 alkyl group, a substituted or unsubstituted C2 to C30 alkenyl group, a substituted or unsubstituted C1 to C30 alkoxy group, a substituted or unsubstituted C7 to C30 arylalkyl group, a substituted or unsubstituted C2 to C30 acyl group, or a substituted or unsubstituted C7 to C30 alkylbenzenesulfonyl group,
R³¹ of the 31nd repeating unit is a substituted or unsubstituted C1 to C30 alkylene group, a substituted or unsubstituted C2 to C30 alkenylene group, a substituted or unsubstituted C1 to C30 alkyleneoxy group, a substituted or unsubstituted C7 to C30 arylalkylene group, a substituted or unsubstituted C2 to C30 acylene group, or a substituted or unsubstituted C7 to C30 divalent alkylbenzenesulfonyl group,
R³² and R³³ are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C2 to C30 acyl group, a substituted or unsubstituted C7 to C30 alkylbenzenesulfonyl group, a substituted or unsubstituted C6 to C30 aryl group, a substituted or unsubstituted C3 to C30 heteroaryl group, a substituted or unsubstituted C7 to C30 arylalkyl group, or a substituted or unsubstituted phenyl group,
X³¹⁻ is a nonmetallic element or a compound anion, and
* represents the binding site.

16. The photoresist composition of claim 12, further comprising a photoinitiator including a photoradical generator.

17. The photoresist composition of claim 12, further comprising a radical quencher.

18. A method of manufacturing an integrated circuit device, the method comprising:
forming a photoresist film on a feature layer by using a photoresist composition comprising a photosensitive polymer and a solvent, the photosensitive polymer comprising a pyridinium salt;
generating radicals from the photosensitive polymer in a first region, which is a portion of the photoresist film, through exposure of the first region to light, and inducing a change in polarity of the photosensitive polymer by converting the pyridinium salt of the photosensitive polymer into a pyridine group; and
forming a photoresist pattern comprising a non-light-exposed region of the photoresist film by removing the light-exposed first region from the photoresist film by using a developer.

19. The method of claim 18, wherein the photosensitive polymer comprises a C1 to C30 alkyl group, in which a secondary or tertiary substituent is bonded to a carbon atom at position 1, 5, or 6 or a heteroatom is bonded to a carbon atom at position 1, 5, or 6, such that a 1,5-hydrogen atom transfer reaction is able to occur.

20. The method of claim 18, wherein the photosensitive polymer comprises a C2 to C30 alkenyl group, which has a double bond between a carbon atom at position 4 and a carbon atom at position 5, between a carbon atom at position 5 and a carbon atom at position 6, or between a carbon atom at position 6 and a carbon atom at position 7, such that an intramolecular cyclization reaction is able to occur.
